(19) United States
(12) Patent Application Publication
(10) Pub. No.: US 2011/0253210 A1
(43) Pub. Date: Oct. 20, 2011

(54) SOLAR CELL AND METHOD FOR MANUFACTURING THE SAME

(76) Inventors: Kyoungsoo LEE, Seoul (KR); Jonghwan KIM, Seoul (KR); Juwan KANG, Seoul (KR); Manhyo HA, Seoul (KR); Daehee JANG, Seoul (KR)

(21) Appl. No.: 12/899,274

(22) Filed: Oct. 6, 2010

(30) Foreign Application Priority Data
Apr. 14, 2010 (KR) 10-2010-0034323

(51) Int. Cl. H01L 31/0236; H01L 31/18

(52) U.S. Cl. 136/256; 438/71; 257/E31.13

(57) ABSTRACT

A method for manufacturing a solar cell includes forming a textured surface having a plurality of jagged portion at a surface of a substrate of a first conductive type; forming an emitter portion by doping an impurity into the substrate, the emitter portion having a second conductive type opposite to the first conductive type; removing a portion of the emitter portion by using a dry etching method, to form an emitter region; forming an anti-reflection layer on the emitter region; and forming a first electrode connected to the emitter region and a second electrode connected to the substrate.

### CROSS-REFERENCE TO RELATED APPLICATION

This application claims priority to and the benefit of Korean Patent Application No. 10-2010-0034323 filed in the Korean Intellectual Property Office on Apr. 14, 2010, the entire contents of which are incorporated herein by reference.

### BACKGROUND OF THE INVENTION

1. Field of the Invention

Embodiments of the present invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells generating electric energy from solar energy have been particularly spotlighted.

A solar cell generally includes semiconductor portions forming a p-n junction by different conductive types from each other such as a p-type and an n-type and electrodes connected to the semiconductor portions, respectively.

When light is incident on the solar cell, a plurality of electron-hole pairs are generated in the semiconductor portions. The electron-hole pairs are separated into electrons and holes by the photovoltaic effect. Thus, the separated electrons move to the n-type semiconductor portion and the separated holes move to the p-type semiconductor portion, The electrons and holes are respectively collected by the electrode electrically connected to the n-type semiconductor portion and the electrode electrically connected to the p-type semiconductor portion. The electrodes are connected to one another using electric wires to thereby obtain electric power.

### SUMMARY OF THE INVENTION

According to an aspect of the present invention, a method for manufacturing a solar cell may include forming a textured surface having a plurality of jagged portion at a surface of a substrate of a first conductive type; forming an emitter portion by doping an impurity into the substrate, the emitter portion having a second conductive type opposite to the first conductive type; removing a portion of the emitter portion by using a dry etching method, to form an emitter region; forming an anti-reflection layer on the emitter region; and forming a first electrode connected to the emitter region and a second electrode connected to the substrate.

The forming the emitter region may remove the portion of the emitter portion, which has an impurity doped concentration equal to or greater than a solid solubility limit of the impurity in the substrate.

The dry etching method may be a reaction ion etching method.

Each of the plurality of jagged portions may have an aspect ratio of about 1.0 to 1.5.

The emitter portion may have a sheet resistance of about 50 Ω/sq to 100 Ω/sq.

The emitter region may have a sheet resistance of about 70 Ω/sq to 120 Ω/sq.

The forming of the textured surface may form the textured surface using the dry etching method.

The dry etching method may be a reaction ion etching method.

The method may further include removing an oxide existing on the emitter portion after the formation of the emitter portion.

The removing of the portion of the emitter portion may remove a substantially equal depth of material from a surface of each of the plurality of jagged portions, and the surface is one that is positioned between an apex portion and a valley portion of the each of the plurality of jagged portions.

According to another aspect of the present invention, a solar cell may include a substrate with a textured surface having a plurality of jagged portions, an emitter region forming a p-n junction with the substrate, a first electrode connected to the emitter region, and a second electrode connected to the substrate, wherein each of the plurality of jagged portions has a diameter and a height of about 300 nm to 800 nm, and a deviation of a sheet resistance of the emitter region is ±10 Ω/sq.

The deviation of the sheet resistance may be a deviation of a sheet resistance in accordance with variation in position of the emitter region in a unit area of about 10 μm×10 μm.

The emitter region may have a sheet resistance of about 70 Ω/sq to 120 Ω/sq.

Each of the plurality of jagged portions may have an aspect ratio of about 1.0 to 1.5.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an example embodiment of the invention;

FIG. 2 is a cross-sectional view taken along a line II-II of FIG. 1;

FIGS. 3A to 3F are sectional views sequentially showing processes for manufacturing a solar cell according to an example embodiment of the present invention;

FIG. 4A show shapes of jagged portions after removal of a dead layer in an emitter region according to an example embodiment of the present invention; and

FIG. 4B show shapes of jagged portions after removal of a dead layer in an emitter region according to a comparative example.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to only the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Referring to the drawings, a solar cell and a method for manufacturing the solar cell according to an example embodiment of the present invention will be described.

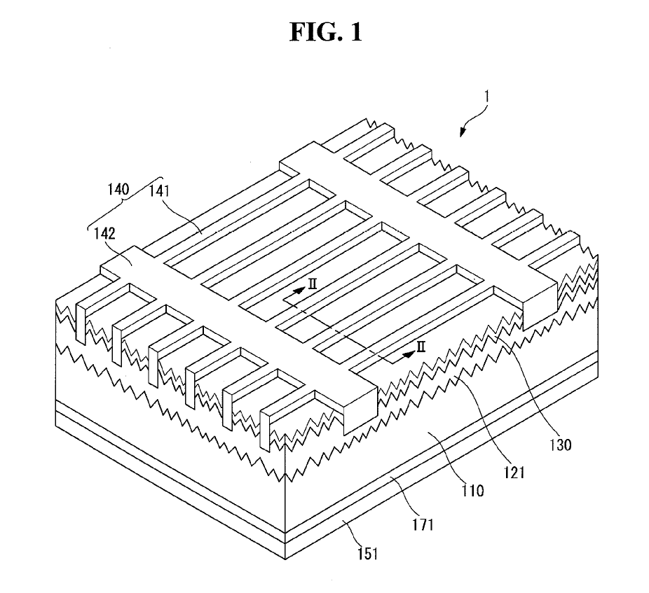

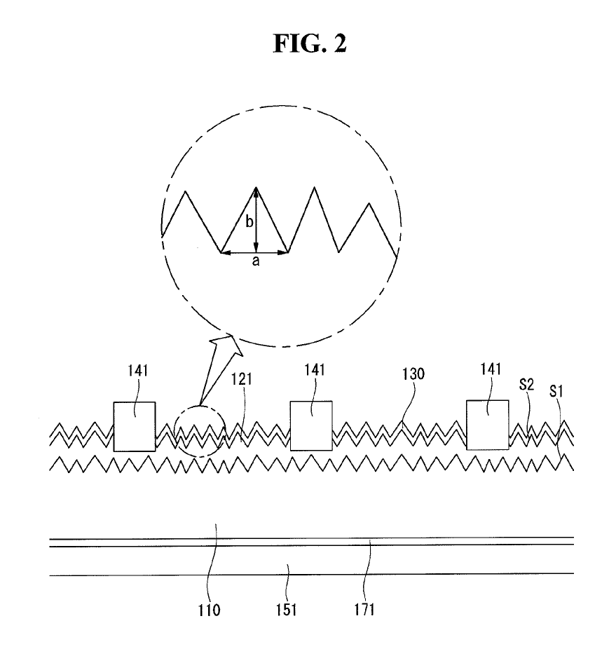

First, one of various examples of a solar cell according to an example embodiment of the present invention will be described in reference to FIGS. 1 and 2.

FIG. 1 is a partial perspective view of a solar cell according to an example embodiment of the invention and FIG. 2 is a cross-sectional view taken along a line II-II of FIG. 1.

Referring to FIGS. 1 and 2, a solar cell 1 according to an example embodiment of the invention includes a substrate 110, an emitter region 121 positioned in (at) a surface (hereinafter, referred to as ‘a front surface’) of the substrate 110 on which light is incident, an anti-reflection layer 130 positioned on the emitter region 121, a front electrode 140 positioned on the front surface of the substrate 110 and connected to the emitter region 121, a rear electrode 151 positioned on a surface (a rear surface) of the substrate 110, opposite the front surface of the substrate 110, on which the light is not incident and connected to the substrate 110, and a back surface field (BSF) region 171 positioned in (at) the rear surface of the substrate 110 and connected to the rear electrode 151.

The substrate 110 is a semiconductor substrate formed of first conductive type silicon, for example, p-type silicon, though not required. In the embodiment, the silicon is polycrystalline silicon, but may be single crystal silicon. If the substrate 110 is of the p-type, the substrate 110 may contain a group III element impurity such as boron (B), gallium (Ga), and indium (In). Alternatively, the substrate 110 may be of an n-type. If the substrate 110 is of the n-type, the substrate 110 may contain a group V element impurity such as phosphorus (P), arsenic (As), and antimony (Sb). Alternatively, the substrate 110 may be materials other than silicon.

The emitter region 121 is an impurity region containing an impurity (e.g., an n-type impurity) of a second conductive type opposite the first conductive type of the substrate 110. The emitter region 121 is substantially positioned in (at) the entire front surface of the substrate 110, on which light is incident.

In this embodiment, the emitter region 121 has a sheet resistance of about 70 Ω/sq. to 120 Ω/sq. In this instance, a deviation of the sheet resistance according to a variation in position is about ±10 Ω/sq. In this embodiment, the deviation of the sheet resistance is a deviation measured in a unit area of about 10 μm×10 μm. However, the unit area for measuring the deviation of the sheet resistance may be changed.

The surface of the emitter region 121, that is, the front surface of the substrate 110 is a textured surface which is an uneven surface, having a plurality of jagged portions.

In this embodiment, each of the jagged portions may have the diameter (a) (i.e., the maximum diameter) and the height (b) of hundreds of nanometers, for example, about 300 nm to 800 nm, respectively, and an aspect ratio (b/a) of each jagged portion may be about 1.0 to 1.5.

By the textured surface, an anti-reflection efficiency of the solar cell 1 is largely improved, and thereby a light amount incident to the substrate 110 increases.

The emitter region 121 forms a p-n junction with the substrate 110. In this instance, an interface of the substrate 110 of the first conductive type and the emitter region 121 of the second conductive type, i.e., a junction portion of the substrate 110 and the emitter region 121 has also an uneven surface under the influence of (or due to) the textured surface of the substrate 110.

By a built-in potential difference generated due to the p-n junction, a plurality of electron-hole pairs, which are generated by incident light onto the semiconductor substrate 110, are separated into electrons and holes, respectively, and the separated electrons move toward the n-type semiconductor and the separated holes move toward the p-type semiconductor. Thus, when the substrate 110 is of the p-type and the emitter region 121 is of the n-type, the separated holes move toward the substrate 110 and the separated electrons move toward the emitter region 121. Accordingly, the holes become major carriers in the substrate 110 and the electrons become major carriers in the emitter region 121.

Because the emitter region 121 forms the p-n junction with the substrate 110, when the substrate 110 is of the n-type, then the emitter region 121 is of the p-type, in contrast to the embodiment discussed above, and the separated electrons move toward the substrate 110 and the separated holes move toward the emitter region 121.

Returning to the embodiment, when the emitter region 121 is of the n-type, the emitter region 121 may be formed by doping the substrate 110 with the group V element impurity of such P, As, Sb, etc., while when the emitter region 121 is of the p-type, the emitter region 121 may be formed by doping the substrate 110 with the group III element impurity such as B, Ga, In, etc.

The anti-reflection layer 130 positioned on the emitter region 121 is preferably, but not necessarily, made of silicon nitride (SiNx) or silicon oxide (SiOx). The anti-reflection layer 130 reduces reflectance of light incident onto the substrate 110 and increases selectivity of a specific wavelength band, thereby increasing efficiency of the solar cell 1. In this embodiment, the anti-reflection layer 130 has a single-layered structure, but the anti-reflection layer 130 may have a multi-layered structure such as a double-layered structure. The anti-reflection layer 130 may be omitted, if desired.

As shown in FIG. 1, the front electrode 140 includes a plurality of finger electrodes 141 and a plurality of bus bars 142.

The plurality of finger electrodes 141 are electrically and physically connected to the emitter region 121, and spaced apart from each other by a predetermined distance to be parallel to each other and extend in a predetermined direction. The plurality of finger electrodes 141 collect charges, for example, electrons, moving toward the emitter region 121.

The plurality of bus bars 142 extend in a direction crossing the finger electrodes 141. The plurality of bus bars 142 are electrically and physically connected to the plurality of finger electrodes 141 as well as the emitter region 121. In this instance, the plurality of bus bars 142 are positioned on the same level layer as the finger electrodes 141, and thereby the plurality of finger electrodes 141 and the plurality of bus bars 142 are electrically and physically connected to each other at positions crossing each other.

Thereby, since the bus bars 142 are connected to the emitter region 121 and the finger electrodes 141, the bus bars 142 collect the charges moving toward the emitter region 121 and charges transferred through the finger electrodes 141, and output the charges to an external device.

Since each bus bar 142 collects and transfers the charges collected by the finger electrodes 141 crossing thereto, each bus bar 142 has a width larger than that of each finger electrode 141.

In the embodiment, FIG. 1 shows two bus bars 142. However, the number of bus bars 142 may be changed. In addition, the width of each bus bar 142 may be also changed based on the number of bus bars 142.

The front electrode 140 having the finger electrodes 141 and the bus bars 142 are preferably, but not necessarily, made of at least one conductive material such as silver (Ag). However, the conductive material may be at least one selected from the group consisting of nickel (Ni), copper (Cu), aluminum (Al), tin (Sn), zinc (Zn), indium (In), titanium (Ti), gold (Au), and a combination thereof. Other conductive materials may be used.

Due to the front electrode 140 being connected to the emitter region 121, the anti-reflection layer 130 is mainly positioned on portions of the emitter region 121, on which the front electrode 140 is not positioned.

The rear electrode 151 is substantially positioned on the entire rear surface of the substrate 110.

The rear electrode 151 contains at least one conductive material such as aluminum (Al) and is connected to the substrate 110.

The rear electrode 151 collects charges, for example, holes, moving toward the substrate 110 and outputs the charges to the external device.

Alternatively, the rear electrode 151 may be a conductive material including at least one selected from the group consisting of Ni, Cu, Ag, Sn, Zn, In, Ti, Au, and a combination thereof. Other conductive materials may be used.

The back surface field region 171 connected to the rear surface of the substrate 110 is an area more heavily doped by an impurity of the same conductive type as the substrate 110, and thereby, in this embodiment, the back surface field region 171 may be a p⁺-type area having an impurity doped concentration heavier than that of the substrate 110.

A potential barrier is formed by an impurity doped concentration difference between the substrate 110 and the back surface field region 171, thereby disturbing the movement of charges (for example, electrons) to a rear portion of the substrate 110. Accordingly, the back surface field region 171 prevents or reduces the recombination and/or the disappearance of the separated electrons and holes in the rear surface of the substrate 110.

The solar cell 1 may further include a plurality of bus bars, that is, a plurality of rear electrode bus bars for the rear electrode 151 positioned on the rear surface of the substrate 110.

Similar to the bus bars 141 of the front electrode 140, the plurality of rear electrode bus bars are connected to the rear electrode 151 to collect the charges mainly transferred from the rear electrode 151 and output the charges to the external device. The plurality of rear electrode bus bars are positioned to correspond to the bus bars 142 of the front electrode 140 and contains at least one conductive material such as silver (Ag).

An operation of the solar cell 1 of the structure will be described in detail.

When light irradiated to the solar cell 1 is incident on the substrate 110 of the semiconductor through the anti-reflection layer 130 and the emitter region 121, a plurality of electron-hole pairs are generated in the substrate 110 by light energy based on the incident light. In this instance, since a reflection loss of light incident onto the substrate 110 is reduced by the anti-reflection layer 130 and the textured surface of the substrate 110, an amount of the incident light on the substrate 110 increases.

The electron-hole pairs are separated by the p-n junction of the substrate 110 and the emitter region 121, and the separated electrons move toward the emitter region 121 of the n-type and the separated holes move toward the substrate 110 of the p-type. The electrons moved toward the emitter region 121 are mainly collected by the finger electrodes 141 and moves along the bus bars 142, while the holes moved toward the substrate 110 are collected by the rear electrode 151. When the bus bars 142 and the rear electrode 151 are connected to electric wires, current flows therein to thereby enable use of the current for electric power.

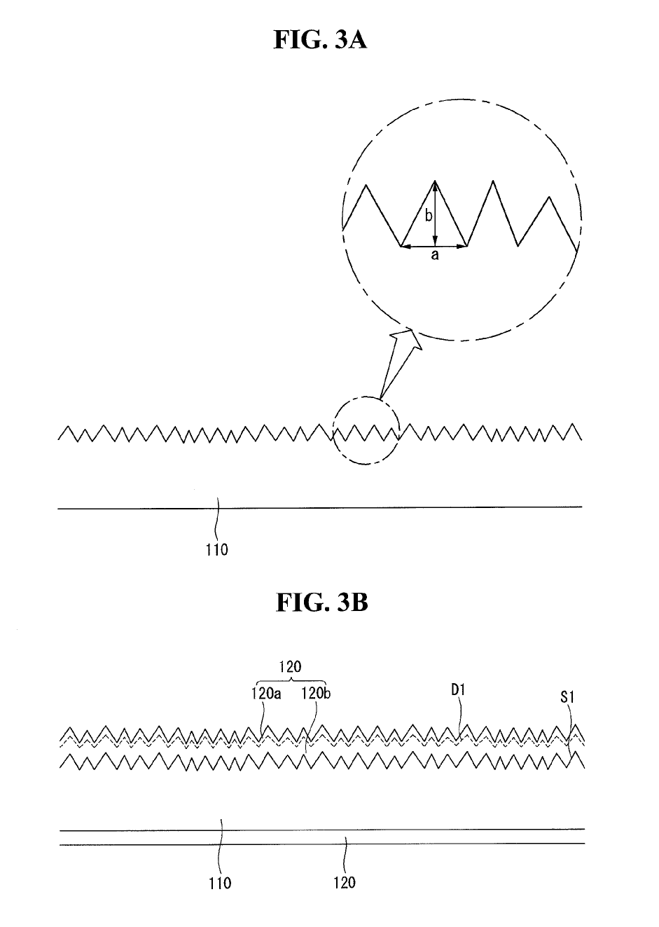

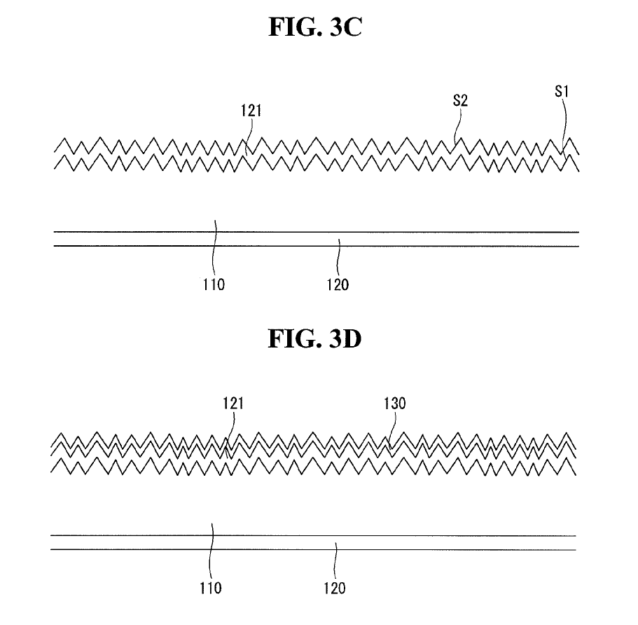

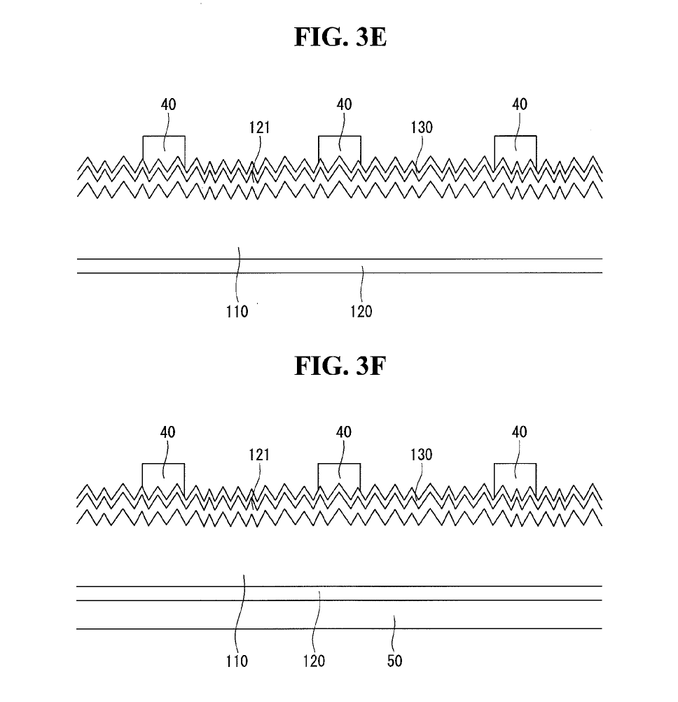

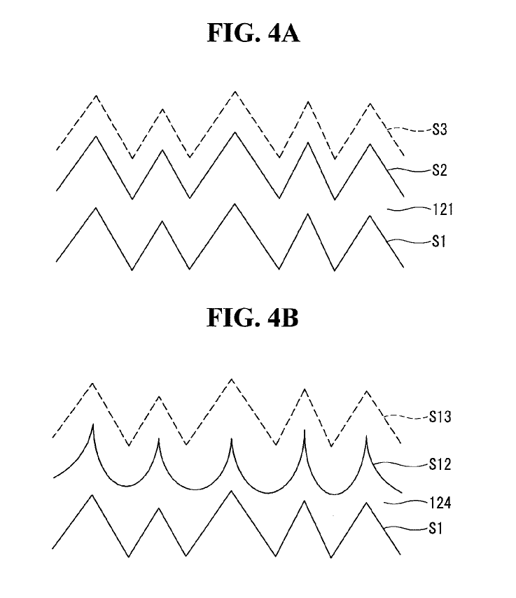

Next, referring to FIGS. 3A to 3F and FIGS. 4A and 4B, a method for manufacturing the solar cell 1 according to an example embodiment of the present invention will be described.

FIGS. 3A to 3F are sectional views sequentially showing processes for manufacturing a solar cell according to an example embodiment of the present invention. FIG. 4A shows shapes of jagged portions after the removal of a dead layer in an emitter region according to an example embodiment of the present invention and FIG. 4B shows shapes jagged portions after the removal of a dead layer in an emitter region according to a comparative example.

As shown in FIG. 3A, an exposed surface, for example, a front surface (an incident surface) of a substrate 110 is etched using a dry etching method such as a reaction ion etching (RIE) method, etc., to form a textured surface having a plurality of jagged portions.

At this time, the substrate 110 is made of p-type polycrystalline silicon, but may be made of single crystal silicon or amorphous silicon of an n-type in other instances.

Each of the jagged portions has a diameter (a) and a height (b) of hundreds of nanometers such as about 300 nm to 800 nm, respectively. In this instance, an aspect ratio (b/a) of each jagged portion may be about 1.0 to 1.5.

Since a size of each jagged portion is small such as hundreds of nanometers, a refractive index from the apex of each jagged portion of a sub-micron size to a rear surface of the substrate 110, which is opposite to the front surface, is gradually changed. That is, an upper portion of the jagged portion has a refractive index similar to that of the air, while a lower portion of the jagged portion has a refractive index similar to that of silicon of the substrate 110. Thus, in each jagged portion, generated is a layer stack effect obtained in stacking layers with different refractive indices which are sequentially changed.

Since the refractive index is changed according to position variation in each jagged portion due to the layer stack effect, the wavelength of light absorbed into the substrate 110 is also changed, and thereby the wavelength range of light absorbed into the substrate 110 also increases. Thus, by the textured surface of the embodiment, reflectance (for example, average weighted reflectance) of light in the wavelength range of about 300 nm to 1100 nm is about 10% or less. Accordingly, an anti-reflection efficiency of light increases to improve efficiency of the solar cell 1.

Next, as shown in FIG. 3B, a high temperature thermal process involving a material (for example, POCl₃ or H₃PO₄) containing a group V element impurity such as P, As, or Sb is performed on the substrate 110 to diffuse (or dope) the group V element impurity into the substrate 110, thus forming an emitter portion 120 which contains the impurity. Hence, the emitter portion 120 is formed in (at) the entire surface of the substrate 110 including a front surface, a rear surface, and side surfaces. Unlike the embodiment discussed above, when the substrate 110 is of the n-type, a high temperature thermal process involving material (for example, B₂H₆) containing a group III element impurity is performed on the substrate 110 to form a p-type emitter portion in the surface of the substrate 110. Next, an oxide such as phosphorous silicate glass (PSG) containing phosphor (P) or boron silicate glass (BSG) containing boron (B) produced when the n-type impurity or the p-type impurity is diffused (or doped) into the substrate 110 is removed through an etching process using HF, etc.

At this time, an example of the process conditions of the RIE etching for forming the textured surface are described as below.

That is, after placing the substrate 110 into a process chamber, an etching gas such as a mixed gas (SF₆/Cl₂) of SF₆ and Cl₂ is injected into the process chamber. In this instance, the chamber may have a pressure of about 0.1 mTorr to 0.5 mTorr, and a mixed ratio of SF₆ and Cl₂ may be about 10:0 to 2.

Then, by applying power of a predetermined magnitude to two electrodes installed at the chamber, plasma is generated at a space between the two electrodes in the chamber based on a raw gas for the plasma to perform an etching, i.e., a dry etching. In this instance, the power applied to the electrodes may be about 3000 W/m² to 6000 W/m².

In this embodiment, the emitter portion 120 has different impurity doped concentrations in accordance with a position of each jagged portion of the textured surface. That is, since the impurity is diffused (or doped) from the surface to an inside of the substrate 110, the impurity doped concentration is progressively greater closer to the surface, that is the textured surface of the substrate 110, and the impurity doped concentration is progressively lower farther from the textured surface.

Thereby, since when progressively closer to the surface of substrate 110, the diffused impurity doped concentration is equal to or greater than a solid solubility (or solid solubility limit) of the impurity in the substrate 110, an amount of impurities (an amount of inactive impurities) which are not normally coupled to materials such silicon (Si) of the substrate 110 among the impurities diffused (doped) into the substrate 110 increases. Thereby, a concentration of the inactive impurities in the emitter portion 120 progressively increases closer to the surface of substrate 110.

For example, when forming the emitter portion 120 of the n-type by diffusing the POCl₃ gas into the p-type substrate 110, clusters in which phosphor (P) is massed are formed, Si—P structures in which silicon (Si) and phosphor (P) are coupled are formed, or phosphor (P) which is not coupled with other elements exists in the substrate 110, and they function as the inactive impurities not normally coupled with silicon (Si).

As described above, since the impurity doped concentration progressively increases closer to the surface of the substrate 110, the inactive impurity concentration also progressively increases closer to the surface of the substrate 110. Thus, the inactive impurities mainly existing near or at the surface of the substrate 110 form a dead layer. However, charges are recombined or disappeared by the inactive impurities existing in the dead layer, to reduce the efficiency of the solar cell 1.

As shown in FIG. 3B, the emitter portion 120 is divided into a high doped portion 120a and a light doped portion 120b. The high doped portion 120a has an impurity doped concentration higher than a predetermined value (D1), for example, the solid solubility, and the light doped portion 120b has an impurity doped concentration less than the predetermined value (D1). The light doped portion 120b is positioned under the high doped portion 120a, and thereby is positioned farther than the high doped portion 120a from the textured surface of the substrate 110. In this instance, when a thickness (i.e., an impurity doped depth) of the emitter portion 120 is about 200 nm to 300 nm, the high doped portion 120a has a thickness of about 80 nm to 100 nm. In addition, a sheet resistance of the emitter portion 120 is about 50 Ω/sq. to 100 Ω/sq., and a deviation of the sheet resistance according to variation in position is about ±2 Ω/sq. in a unit area of 10 μm×10 μm. In this embodiment, a magnitude of the solid solubility may be changed based on a diffusion temperature or kinds of impurities, etc.

Further, in each jagged portion, the impurity doped concentration is varied in accordance with variation in position with the jagged portion thereof. For example, in each jagged portion, an impurity concentration of an apex portion is higher than that of the remaining portion.

To prevent or reduce the charge loss due to the high doped portion 120a (i.e., the dead layer) of the emitter portion 120, as shown in FIG. 3C, the high doped portion 120a is removed by the dry etching method such as the RIE, to form an emitter region 121, similar to the etching method for forming the textured surface of the substrate 110.

As compared to the formation of the textured surface, the magnitude of power applied to the two electrodes for removing the high doped portion 120a may be different, but the pressure of the chamber and the etching gas may be equal or at least similar.

Thereby, the pressure of the chamber may be 0.1 to 0.5 mTorr and the etching gas may be the mixed gas (SF₆/Cl₂) of SF₆ and Cl₂. In this instance, the mixed ratio of the etching gas (SF₆/Cl₂) may be about 10:0 to 2. However, the magnitude of the power applied to the two electrodes is defined or set to remove the dead layer formed in the surface of the emitter portion 120, and thereby is less than the magnitude of the power applied in forming the plasma. For example, the magnitude of the power for removing the dead layer may be about 300 W/m² to 600 W/m².

When the magnitude of the power is more than about 600 W/m², the surface of the emitter portion 120 is damaged by plasma generated by the application of the power, and an excessive amount of emitter portion 120 is removed, leading to an increase in the sheet resistance of the emitter region 121. When the magnitude of the power is less than about 300 W/m², plasma is not normally generated or sufficiently generated so as to disturb an etching operation of the dead layer and to thereby not normally or sufficiently remove a desired amount of the dead layer.

As described above, for removing the dead layer of the emitter portion 120, since the dry etching method (ex. RIE) is used in which the control of an etched time or an etched amount is easy, the etched amount (and/or etched depth) from the surface of the emitter portion 120 is substantially regular irrespective of a position thereof. Thereby, an etched speed at the apex portion and a side portion of each jagged portion, and a portion (i.e., a valley portion) between adjacent two jagged portions is substantially equal to each other. Accordingly, as shown in FIG. 4A, a shape of the surface (S2) of the emitter region 121 after the removal of a portion of the emitter portion 120 is substantially equal to that of the textured surface (S3) of the substrate 110 before the removal of the portion of the emitter portion 120.

A thickness of the emitter portion 120, that is, a thickness of the textured surface (from S3 to S2) of the substrate 110 removed by the etching operation of the high doped portion 120a is about tens of nanometers. Accordingly, an etched depth from the surface of the respective jagged portion (i.e. the surface that is positioned between the apex portion and the valley portion, and including the valley portion) is substantially equal or consistent.

By the removal of the high doped portion 120a, the thickness of the emitter region 121 is less than that of the emitter portion 120, and thereby the sheet resistance of the emitter region 121 becomes more than that of the emitter portion 120. For example, the sheet resistance of the emitter region 121 may be about 70 Ω/sq. to 120 Ω/sq., and, in this instance, a deviation of the sheet resistance in accordance with the position variation in a unit area of about 10 μm×10 μm is about ±10 Ω/sq.

As compared to a case in removing the high doped portion 120a using a wet etching method, the shape of the textured surface of the substrate 110 before and after the removal of the portion (the dead layer) of the emitter portion 120 in this embodiment is not largely changed, and thereby a variation of an average weighted reflectance due to a shape change of the textured surface substantially does not occur.

That is, when the portion of the emitter portion 120 is removed by the wet etching method, a concentration of an etchant in a bath is changed in accordance with position, and the removed amount is varied according to a permeated amount of an etchant, such that the control of etch environments such as the etched speed, the etched amount, or an etched direction is difficult. Thereby, unlike the dry etching method, the etched amount of the wet etching method is varied in accordance with the position variation of the textured surface. For example, an amount etched in the valley portion was more than an amount etched in the apex portion of each jagged portion, to show isotropic etching characteristics.

Thus, when the textured surface is etched by the wet etching method, the etched amount of the valley portion becomes larger as compared to the remaining portion of each jagged portion, and thereby, as shown in FIG. 4B, a shape of a surface (S12) of an emitter region 124 after the removal of the portion of the emitter portion does not follow the shape of the textured surface (S13). In this instance, the textured surface S13 may be one formed by the dry etching method or the wet etching method.

Thus, in the wet etching method for removal of the dead layer, since the etched amount in the valley portion is larger than that in the apex portion of each jagged portion, an aspect ratio of a jagged portion of the emitter region 124 after the removal of the dead layer and a deviation of the sheet resistance in accordance with the position variation increase. For example, the aspect ratio of each jagged portion of the emitter region 124 was about 2.0 to 2.5 and the deviation of the sheet resistance increased to about ±15 Ω/sq.

When the dead layer of the emitter portion is removed by the dry etching method instead of the wet etching method to complete the emitter region 121, the aspect ratio of the jagged portion of the emitter region 121 is not substantially changed as compared to the textured surface of the substrate 110, and thereby the anti-reflection effect by the textured surface of the substrate 110 is equally maintained after the removal of the portion of the emitter portion 120.

In addition, since the deviation of the sheet resistance is decreased after the removal of the portion of the emitter portion 120 in using the dry etching method, a sheet resistance difference according to the position variation of the emitter region 121 is reduced to improve operation characteristics of the emitter region 121.

Next, as shown in FIG. 3D, an anti-reflection layer 130 is formed on the emitter region 121 positioned at the front surface of the substrate 110 using plasma enhanced chemical vapor deposition (PECVD), etc.

Sequentially, as shown in FIG. 3E, a front electrode paste containing Ag and glass frit is applied on corresponding portions of the anti-reflection layer 130 using a screen printing method and then is dried to form a front electrode pattern 40. The glass frit contains lead (Pb), etc.

At this time, the front electrode pattern 40 includes a portion for a plurality of finger electrodes and a portion for a plurality of bus bars.

Next, as shown in FIG. 3F, a rear electrode paste containing aluminum (Al) is applied on the rear surface of the substrate 110 using the screen printing method and then is dried, to form a rear electrode pattern 50 on the emitter portion 120 formed at (in) the rear surface of the substrate 110.

At this time, a temperature for drying the patterns 40 and 50 may be about 120° C. to 200° C. Additionally, a formation order of the patterns 40 and 50 may vary.

Next, a firing process is performed on the substrate 110, on which the front electrode pattern 40 and the rear electrode pattern 50 are formed at a temperature of about 750° C. to 800° C., to form a front electrode 140 including the plurality of finger electrodes 141 and the plurality of bus bars 142 and connected to portions of the emitter region 121, a rear electrode 151 connected to the substrate 110, and a back surface field region 171 formed in (at) the rear surface of the substrate 110 and connected to the rear electrode 151.

More specifically, when the thermal process is performed, by functions of lead (Pb) etc., contained in the front electrode pattern 40, the front electrode pattern 40 passes through portions of the anti-reflection layer 130 underlying the front electrode pattern 40 and comes in contact with the emitter region 121 to form the front electrode 140 connected to the emitter region 121.

In addition, during the thermal process, aluminum (Al) contained in the rear electrode pattern 50 is diffused (or doped) over the emitter portion 120 formed at the rear surface of the substrate 110 to form an impurity region, that is, the back surface field region 171 that is highly doped with an impurity of the same conductive type as the substrate 110. In this instance, an impurity doped concentration of the back surface field region 171 is higher than that of the substrate 110.

The rear electrode pattern 50 is electrically connected to the substrate 110 through the back surface field region 171, to form the rear electrode 151.

Thereby, by an impurity doped concentration difference between the substrate 110 and the back surface field region 171, the back surface field region 171 prevents or reduces the recombination and/or disappearance of separated electrons and holes in a rear portion of the substrate 110 and helps the movement of the holes toward the rear electrode 151.

Moreover, in performing the thermal process, metal components contained in the respective electrode patterns 40 and 50 are chemically coupled to the contacted portions 121 and 110, respectively, such that a contact resistance is reduced and thereby a transmission efficiency of the charges is improved to improve a current flow.

Then, an edge isolation process is performed to remove the impurity portion in an edge portion or side sides of the substrate 110 using laser beams or an etching process and to thereby complete the solar cell 1 as shown in FIGS. 1 and 2. A performing time of the edge isolation process may be changed if it is necessary.

In this embodiment, the emitter portion 120 formed in (at) the rear surface of the substrate 110 is not removed. However, alternatively, before the formation of the rear electrode pattern 50, a separate process may be performed to remove the emitter portion 120 formed in (at) the rear surface of the substrate 110.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

1. A method for manufacturing a solar cell, the method comprising:
forming a textured surface having a plurality of jagged portion at a surface of a substrate of a first conductive type;
forming an emitter portion by doping an impurity into the substrate, the emitter portion having a second conductive type opposite to the first conductive type;
removing a portion of the emitter portion by using a dry etching method, to form an emitter region;
forming an anti-reflection layer on the emitter region; and
forming a first electrode connected to the emitter region and a second electrode connected to the substrate.

2. (canceled)

3. The method of claim 1, wherein the dry etching method is a reaction ion etching method.

4. The method of claim 1, wherein each of the plurality of jagged portions has an aspect ratio of 1.0 to 1.5.

5. The method of claim 1, wherein the emitter portion has a sheet resistance of 50 Ω/sq to 100 Ω/sq.

6. The method of claim 1, wherein the emitter region has a sheet resistance of 70 Ω/sq to 120 Ω/sq.

7. The method of claim 1, wherein the forming of the textured surface forms the textured surface using the dry etching method.

8. The method of claim 7, wherein the dry etching method is a reaction ion etching method.

9. The method of claim 1, further comprising removing an oxide existing on the emitter portion after the formation of the emitter portion.

10. (canceled)

11. A solar cell, comprising:
a substrate with a textured surface having a plurality of jagged portions;
an emitter region forming a p-n junction with the substrate;
a first electrode connected to the emitter region; and
a second electrode connected to the substrate,
wherein each of the plurality of jagged portions has a diameter and a height of 300 nm to 800 nm, and a deviation of a sheet resistance of the emitter region is ±10 Ω/sq.

12. The solar cell of claim 11, wherein the deviation of the sheet resistance is a deviation of a sheet resistance in accordance with variation in position of the emitter region in a unit area of 10 μm×10 μm.

13. The solar cell of claim 11, wherein the emitter region has a sheet resistance of 70 Ω/sq to 120 Ω/sq.

14. The solar cell of claim 11, wherein each of the plurality of jagged portions has an aspect ratio of 1.0 to 1.5.
